(19) United States
(12) Patent Application Publication
(10) Pub. No.: US 2008/0220288 A1
(43) Pub. Date: Sep. 11, 2008

(54) Light-Emitting Device, And Method For The Manufacture Thereof

(75) Inventors: Margreet De Kok, Eindhoven (NL); Albert Van Dijken, Eindhoven (NL); Suzanna Helena Petronella Maria De Winter, Eindhoven (NL); Bea Maria Wilhelmina Langeveld-Voss, Eindhoven (NL); Jolanda Johanna Anna Maria Bastiaansen, Eindhoven (NL); Albert Jos Jan Marie Van Breemen, Eindhoven (NL); Nicole Maria Matthias Kiggen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/067,049

(22) PCT Filed: Sep. 8, 2006
(86) PCT No.: PCT/IB2006/053186

§ 371 Date: Mar. 17, 2008

(30) Foreign Application Priority Data
Sep. 15, 2005 (EP) 05108451.5

(51) Int. Cl. B32B 9/00; C09K 11/00; H05B 33/10; H05B 33/00

(52) U.S. Cl. 428/690; 427/66

(57) ABSTRACT

A light-emitting device comprising an anode; a cathode; a light-emitting layer arranged between said anode and said cathode; and a buffer layer, comprising a conducting polymer and a polymeric acid, arranged between said anode and said light-emitting layer, is disclosed. Acidic groups of said polymeric acid have been converted to non-acidic groups in at least a part of said buffer layer, which minimises acid quenching of photoluminescence. A method for manufacturing such a device is also disclosed.

### FIELD OF THE INVENTION

The present invention relates to light-emitting devices and methods for the manufacture of such devices.

### BACKGROUND OF THE INVENTION

In a polymer light-emitting diode the light-emitting polymer layer is supported by a buffer layer, which serves to facilitate the injection of holes from the anode side. Furthermore, this buffer layer protects the device from short circuiting as it smoothens particles and possible spikes in the anode. Typical conducting polymers used as buffer material are polydioxythiophenes, such as poly-(ethylenedioxythiophene) (PEDOT), and polyaniline.

These materials can be prepared by polymerising aniline or dioxythiophene monomers in aqueous solution in the presence of a water soluble polymeric acid, such as poly(styrenesulfonic acid) (PSSA).

The polymeric acid stabilises the positive charges and keeps the combination of polymers soluble in water. PSSA is a strong acidic material and in the solid content of 2-3% it has a pH value of about 1.5.

It is known (G. Zotti, S. Zecchin, G. Schiavon, F. Louwet, L. Groenendaal, X. Crispin, W. Osikowicz, W. Salaneck, M. Fahlman, Macromolecules 2003, 36, 3337; X. Crispin, S. Marciniak, W. Osikowicz, G. Zotti, A. W. Denier van der Gon, F. Louwet, M. Fahlman, L. Groenendaal, F. de Schryver, W. R. Salaneck, J. Pol. Science Part B: Polymer Physics 2003, 41, 2561; G. Greczynski, Th. Kugler, M. Keil, W. Osikowicz, M. Fahlman, W. R. Salaneck, J. Electron. Spectrosc. Relat. Phenom. 2001, 121, 1; G. Greczynski, Th. Kugler, W. R. Salaneck, Thin Solid Films 1999, 354, 129; G. Greczynski, Th. Kugler, W. R. Salaneck, J. Appl. Phys. 2000, 88, 7187; P. C. Jukes, S. J. Martin, A. M. Higgins, M. Geoghegan, R. A. L. Jones, S. Langridge, A. Wehrum, S. Kirchmeyer, Adv. Mater. 2004, 16, 807) that the top of the PEDOT:PSSA layer at the interface with the light-emitting polymer is enriched in PSSA (FIG. 1). This acidic environment quenches the electroluminescence of the light-emitting polymer, and thus deteriorates the performance of the device.

In WO 2004/084260, the use of an intermediate layer between the buffer layer and the light-emitting polymer layer is suggested. By using this layer the direct interaction between buffer and light-emitting polymer is prohibited and, as a result, acid-induced quenching is minimized.

However, the application of an intermediate layer in a device means an additional processing step as a third layer has to be spin coated or printed. Despite the increase in efficiency and lifetime, which has been obtained by the use of an intermediate layer, incorporation of this third step is technologically very unfavorable, resulting in a severe decrease of yield in the production lines. Therefore, an alternative solution to the problem of acid-induced quenching has been very much sought after.

### SUMMARY OF THE INVENTION

An object of the present invention is to overcome the disadvantage of electroluminescence quenching in light-emitting devices comprising an acidic buffer layer.

Thus, the present invention relates to a light-emitting device comprising an anode; a cathode; a light-emitting layer arranged between said anode and said cathode; and a buffer layer, comprising a conducting polymer and a polymeric acid, arranged between said anode and said light-emitting layer. The buffer layer comprises acidic groups of the polymeric acid, which have been converted to non-acidic groups in at least a part of said buffer layer. The non-acidic groups are preferably arranged in a part of said buffer layer facing said light-emitting layer. Thereby, the acid induced quenching is minimised, and the performance of the device is improved.

The non-acidic groups may e.g. have converted from acidic groups by esterification with an esterification agent, such as an orthoformate having the general formula (I):

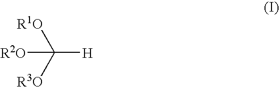

in which R¹, R², and R³, being identical or different, are selected from linear, branched or cyclic alkyl groups having from 1 to 20 carbon atoms, wherein, in said alkyl groups, one or more not neighbouring CH₂-groups are optionally substituted by —O—, —S—, —P—, —Si—, —CO—, —COO—, —O—CO—, —N-alkyl-, —N-aryl- or —CON-alkyl-, and one or more H-atoms are optionally substituted by CN, Cl, F or an aryl group.

A preferred esterification agent is triethylorthoformate.

The non-acidic groups may for example be esterified sulphonic acid groups, in which case the acidic groups are sulphonic acid groups.

The buffer layer may e.g. comprise PEDOT:PSSA, and the light-emitting layer may e.g. comprise a light-emitting polymer or a light-emitting small organic molecule. The light-emitting device may e.g. be a polymer light-emitting diode (PLED), or an organic light-emitting diode (OLED).

The present invention also relates to a method for manufacturing a light-emitting device comprising: providing an anode; providing a cathode; arranging a light-emitting layer between said anode and said cathode; arranging a buffer layer, comprising a conducting polymer and a polymeric acid, between said anode and said light-emitting layer; and performing a conversion of acidic groups of said polymeric acid to non-acidic groups in at least a part of said buffer layer.

The conversion of acidic groups of the polymeric acid to non-acidic groups is preferably performed in a part of said buffer layer facing said light-emitting layer. In practice, the conversion of acidic groups to non-acidic groups is performed on the surface of the buffer layer before arranging the light-emitting layer thereon.

The conversion may e.g. be performed by esterification with an esterification agent. The esterification is suitably performed by spin coating or ink jet printing said esterification agent onto said buffer layer, and then esterifying the acidic groups.

The esterification agent may e.g. be an orthoformate according to formula (I) above, preferably triethylorthoformate.

### BRIEF DESCRIPTION OF THE DRAWINGS

FIG. 1 is a visualisation of the acidic interface between PEDOT:PSSA and light-emitting polymer in prior art devices.

FIG. 2 shows a device according to the invention, in which the sulphonic acid groups are esterified, i.e. converted to non-acidic groups, at the interface between PEDOT:PSSA and light emitting polymer.

FIG. 3 shows the current density as a function of the applied voltage for a prior art device (Reference) and for a device according to the invention (TEOF).

FIG. 4 shows the efficacy as a function of current density for a prior art device having a non-modified PEDOT:PSSA-buffer layer.

FIG. 5 shows the efficacy as a function of current density for a device according to the invention, having a PEDOT:PSSA-buffer layer esterified with diluted triethyl-orthoformate (TEOF).

FIG. 6 shows the efficacy as a function of current density for a device according to the invention, having a PEDOT:PSSA-buffer layer esterified with TEOF.

### DETAILED DESCRIPTION OF THE INVENTION

In the research work leading to the present invention, a new concept of protecting a light-emitting layer from the acidity of an adjacent buffer layer in a light-emitting device was developed.

More particularly, a method to shield the light-emitting polymer from the acidic groups of the buffer layer in a polymer light emitting diode (PLED) was invented.

Basically, a light-emitting device comprises a light-emitting layer sandwiched between two electrical contact layers, i.e. an anode and a cathode. The buffer layer is positioned between the light-emitting layer and the anode in order to increase hole injection from the anode, and planarise the anode surface.

The buffer layer, which may also be referred to as a hole-transport layer, a hole-injecting layer, or a part of a bilayer anode, comprises a conducting polymer and a polymeric acid.

Examples of conducting polymers are polyaniline (PANi), polydioxythiophenes, such as poly(ethylenedioxy-thiophene) (PEDOT), and polythiophene derivatives.

Examples of polymeric acids are poly(styrene-sulphonic acid) (PSSA) and poly(acrylamidoalkylsulphonic acids), e.g. poly(acrylamido-2-methyl-1-propanesulphonic acid) (PAAMPSA). Other examples of polymeric acids are carbonic acids and phosphonic acids, which also bear the proton, which is captured by the modification according to the present invention.

The conducting polymer and the polymeric acid form a polymer dispersion in water. Examples of polymer mixtures which may be used as a buffer layer according to the present invention are: PEDOT/PSSA, PEDOT/PAAMPSA, PANi/PSSA and PANi/PAAMPSA.

The weight ratio of conducting polymer:polymeric acid may for example be in the range of 1:1 to 1:20, or in the range of 1:3 to 1:8. For example, the weight ratio of PEDOT:PSSA may be 1:6.

In polymer light emitting diodes, the weight ratio of conducting polymer:polymeric acid is normally in the range of 1:6 to 1:20.

As used herein, the term “light-emitting layer” relates to a layer, which emits light when a sufficient bias voltage is applied to the electrical contact layers, i.e. the anode and cathode.

The light-emitting layer may e.g. contain polymeric materials. Light-emitting diodes (LEDs) with a light-emitting layer comprised of polymeric materials are referred to as polymer light-emitting diodes (PLEDs).

A preferred polymeric material for use in the light-emitting layer according to the invention is NK 329 blue emitting material, which structure is shown in formula (II) below:

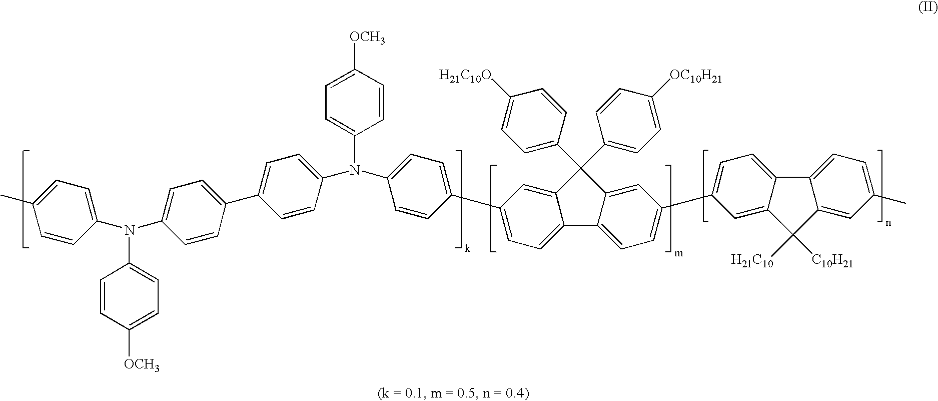

Alternatively, the light-emitting layer may contain organic electroluminescent compounds (emitters), such as, for example small organic molecule emitters, oligomeric emitters, or dendrimeric emitters.

LEDs with a light-emitting layer comprised of small organic molecule materials are referred to as OLEDs.

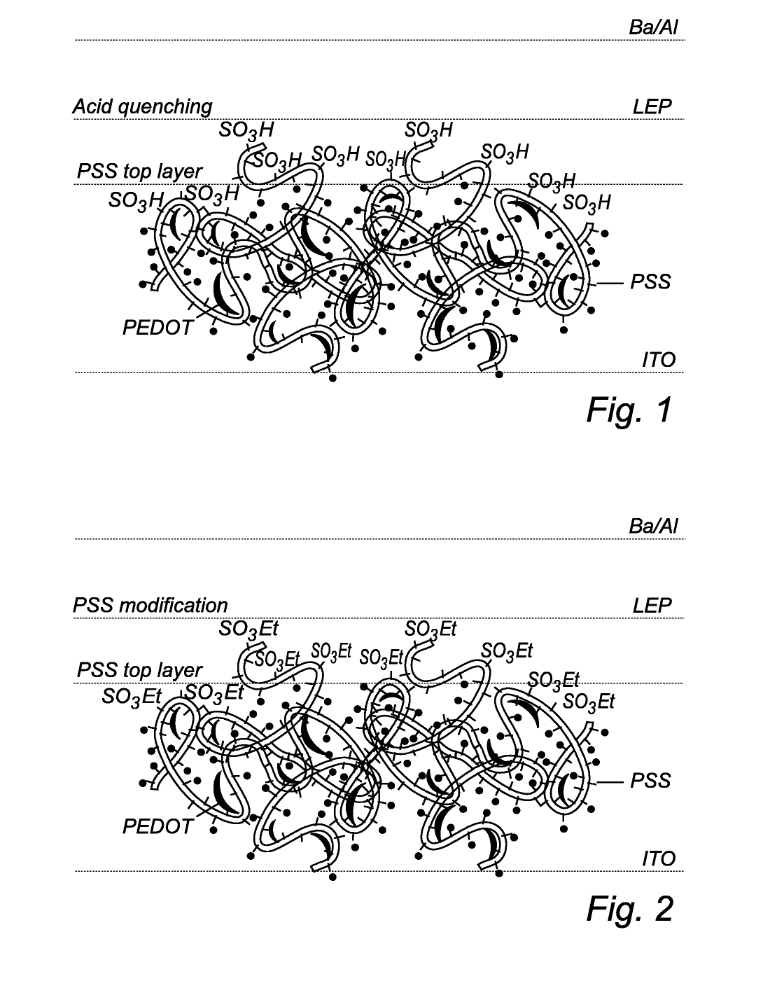

As illustrated in FIG. 1, there is an enrichment of acidic groups in the part of the buffer layer facing the light-emitting layer. In the specific example shown, the acidic groups are sulphonic acid groups, the buffer layer is PEDOT/PSSA, and the light-emitting layer is a light-emitting polymer (LEP).

The present inventors have, very surprisingly, found a technologically feasible method to shield the light-emitting layer from the acidic groups. More particularly, the present inventors have suggested the conversion of the acidic groups enriched in the interface area between the buffer layer and the light-emitting layer to non-acidic groups. Moreover, as a result, the acid-induced quenching is minimized and an increase in efficiency in the devices has been established. An example of such a conversion is shown in FIG. 2.

As used herein, the term “acidic groups” relates to functional groups in the buffer or hole injection layer, which have a negative effect on the electroluminescent performance of the light generating material. These groups can be modified by a chemical reaction, which alters the acid functionality.

As used herein, the term “non-acidic groups” relates to the modified acid functionalities after chemical reaction, which shields the light-emitting layer from the negative effect of the buffer or hole injection layer.

The conversion of acidic groups to non-acidic groups is suitably performed in the part of the buffer layer facing the light-emitting layer. Thus, there will be essentially no acidic groups in the part of the buffer layer facing the light-emitting layer, while there will be acidic groups in the part of the buffer layer facing the anode. However, all acidic groups in the buffer layer may be converted to non-acidic groups. The acidic groups may be converted before or after application of the light-emitting layer.

As used herein, the term “a part of said buffer layer facing said light-emitting layer” refers to the part of the buffer layer, which is in contact with the light-emitting layer in the completed device.

One way of converting the acidic groups to non-acidic groups is to esterify the acidic groups by an esterification agent. As used herein, the term “esterification agent” relates to a chemical reagent having the ability to transform an acid into an ester functionality by which the pKa or acidic character is diminished.

For example, when PSSA is used as a polymeric acid in the buffer layer, the acidic groups are sulphonic acid groups, which may be converted to esterified, non-acidic, sulphonic acid groups by using an orthoformate having the general formula (I):

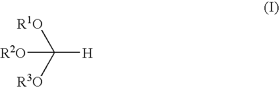

in which R¹, R², and R³, being identical or different, are selected from linear, branched or cyclic alkyl groups having from 1 to 20 carbon atoms, wherein, in said alkyl groups, one or more not neighbouring CH₂-groups are optionally substituted by —O—, —S—, —P—, —Si—, —CO—, —COO—, —O—CO—, —N-alkyl-, —N-aryl- or —CON-alkyl-, and one or more H-atoms are optionally substituted by CN, Cl, F or an aryl group.

A preferred orthoformate according to the invention is where R₁, R₂ and R₃ are H₂C—CH₃, i.e. the compound of formula (I) is triethylorthoformate. Other orthoformates according to formula (I) include: triisopropyl orthoformate, trimethyl orthoformate, trioctadecyl orthoformate, tripropyl orthoformate, tris(methylthio)methane orthoformate, tris(phenylthio)methane orthoformate, tributyl orthoformate, tripentyl orthoformate, and triethyl orthoformate (all available from Aldrich). Derivatives of orthoformates may also be used.

The esterification agent may be used alone, or it may be diluted with an organic solvent, e.g. toluene.

The conversion, by esterification using triethylorthoformate, of sulphonic acid groups to sulphonates as esterified non-acidic sulphonic acid groups is illustrated by the following reaction scheme (III)

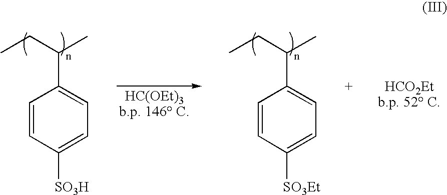

An advantage of the method mentioned above is the fact that the side product of the esterification reaction, a formate, is either volatile under the processing conditions used or can be removed easily by rinsing the modified buffer layer with a suitable solvent.

There are also other methods that could be used for conversion of the acidic groups to non-acidic groups.
Some examples are given below:

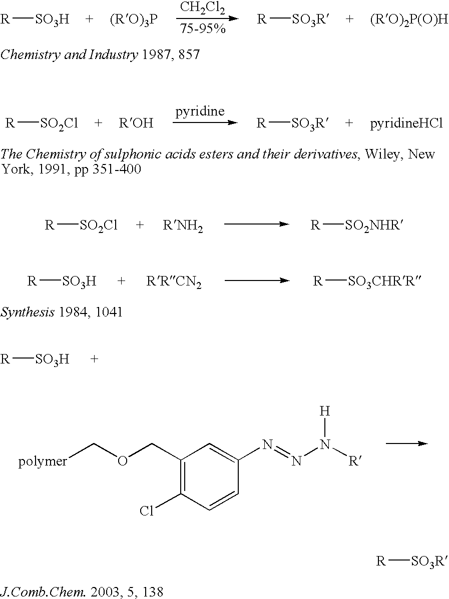

A device according to the invention generally also includes a substrate, which can be adjacent to the anode or the cathode. Most frequently, the substrate is adjacent to the anode. The substrate can be flexible or rigid, organic or inorganic. Generally, glass or flexible organic films are used as a support.

The inorganic anode is an electrode that is particularly efficient for injecting or collecting positive charge carriers. The anode can be a metal, a mixed metal, an alloy, a metal oxide or a mixed-metal oxide. Examples of suitable anode materials are indium-tin-oxide (ITO), or other transparent conducting oxides such as ZnO or thin transparent metal layers like Al, Ag, or Pt.

The cathode is an electrode that is particularly efficient for injecting or collecting electrons or negative charge carriers. The cathode can be any metal or non-metal having a lower work function than the anode. Examples of suitable cathode materials are aluminum, calcium, barium, magnesium, silver and zinc selenide (which is transparent and conductive) as well as combinations or stacks thereof. The cathode may additionally contain an injection layer, such as lithium fluoride (LiF) or the like.

Other layers may also be included in a light-emitting device according to the invention, which will be evident to a man skilled in the art. In addition, any of the above-described layers can be made of two or more layers. Further, some layers may be surface treated to increase charge carrier transport efficiency.

The device can be prepared by sequentially depositing the individual layers on a suitable substrate. In most cases the anode is applied to the substrate and the layers are built up from there. In general, the different layers will have the following range of thicknesses: inorganic anode, 5-500 nm, preferably 100-200 nm (a metal layer should be sufficiently thin to be transparent, i.e. in the range of 5-20 nm); buffer layer, 5-250 nm, preferably 20-200 nm; light-emitting layer, 1-100 nm, preferably 60-100 nm; cathode layer, 20-1000 nm, preferably 30-500 nm.

The inorganic anode layer is usually applied by a vacuum deposition process.

The light-emitting layer can be applied from solutions by any conventional means, including spin coating, casting, and printing. The light-emitting layer can be applied directly by vapor deposition processes, depending upon the nature of the materials. It is also possible to apply an active polymer precursor and then convert to the polymer, typically by heating.

The buffer layer can be applied using any conventional means, including spin-coating, casting, and printing, such as gravure printing. The buffer layer can also be applied by ink jet printing.

The cathode layer is usually applied by a physical vapor deposition process.

The conversion of the acidic groups of the buffer layer is technologically easy to be implemented and can for example be carried out as follows:
Spin coating/ink jet printing and baking of the buffer layer, e.g. PEDOT:PSS from a solution of 0.5%-3%, preferably 1-2%, in water. Baking is done at temperatures above 100° C., preferably above 180° C.
Spin coating/ink jet printing of the esterification agent, e.g. liquid triethylorthoformate, possibly diluted with toluene, or an alternative solvent.
Baking of the stack by which esterification takes place at elevated temperature, preferably between 50 and 250° C., more preferably between 100 and 225° C. and most preferably between 180 and 210° C.
Spin coating/ink jet printing of light-emitting polymer from an organic solvent, such as toluene or xylene, chlorinated solvents or any other orthogonal solvent which does not dissolve the underlying PEDOT/PSSA layer.

The above described process is suitable also for other esterification agents.

### EXAMPLE

Light emitting devices were prepared using the standard protocol and standard materials with NK 329 as blue light-emitting polymer. The structure of NK 329 blue emitting material is shown in formula (III) below.

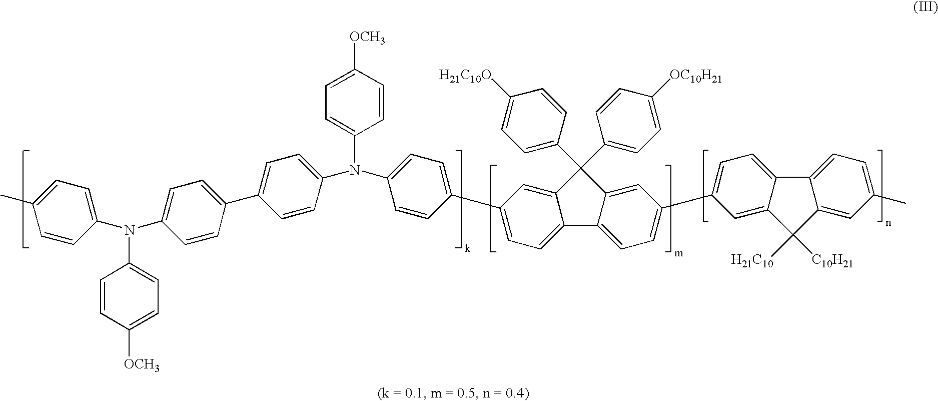

Devices in which the buffer layer has been treated with triethylorthoformate have been compared to reference devices.

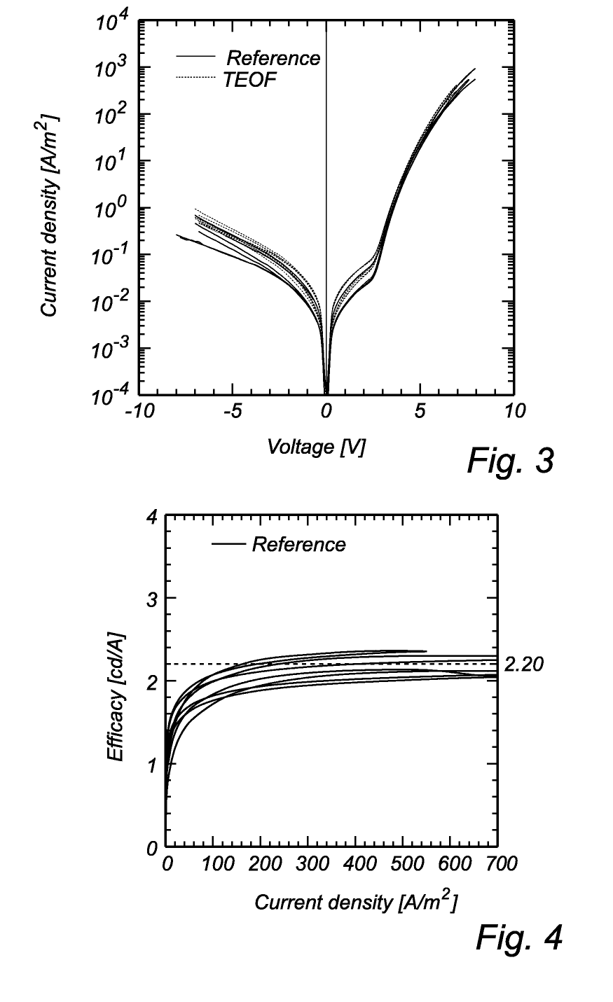

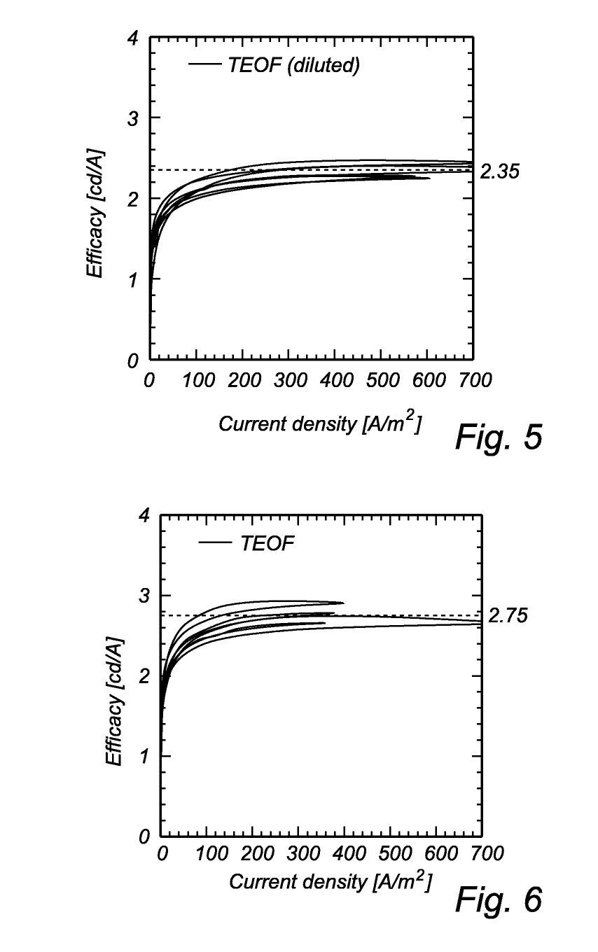

Pure triethylorthoformate and triethylorthoformate diluted with toluene (3:1 TEOF:toluene) were used as esterification agents. Devices were processed and characterised. The esterification did not result in a modification of the buffer layer thickness nor did it influence the current density (see FIG. 3). However, the efficiency is increased as a result of the esterification (see FIGS. 4 to 6 and table 1).

TABLE 1
Efficacy of blue LEDs exhibited per modified buffer layer

| Type | Average efficacy [cd/A] | Increase (%) |
|---|---|---|
| Reference | 2.20 | 0 |
| diluted TEOF | 2.35 | 7 |
| undiluted TEOF | 2.75 | 25 |

As evident from the above experimental data, by the present invention it is possible to obtain an increase of 25% in the efficiency of this blue light-emitting polymer with a straightforward process step that is technologically implementable.

1. A light-emitting device comprising:
an anode;
a cathode;
a light-emitting layer arranged between said anode and said cathode;
a buffer layer, comprising a conducting polymer and a polymeric acid, arranged between said anode and said light-emitting layer;
characterized in that acidic groups of said polymeric acid have been converted to non-acidic groups in at least a part of said buffer layer.

2. A light-emitting device according to claim 1, wherein said non-acidic groups are arranged in a part of said buffer layer facing said light-emitting layer.

3. A light-emitting device according to claim 1, wherein said non-acidic groups have been converted from acidic groups by esterification with an esterification agent.

4. A light-emitting device according to claim 3, wherein said esterification agent is an orthoformate having the general formula (I): 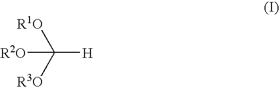
in which R¹, R², and R³, being identical or different, are selected from linear, branched or cyclic alkyl groups having from 1 to 20 carbon atoms, wherein, in said alkyl groups, one or more not neighbouring CH₂-groups are optionally substituted by —O—, —S—, —P—, —Si—, —CO—, —COO—, —O—CO—, —N-alkyl-, —N-aryl- or —CON-alkyl-, and one or more H-atoms are optionally substituted by CN, Cl, F or an aryl group.

5. A light-emitting device according to claim 4, wherein said esterification agent is triethylorthoformate.

6. A light-emitting device according to claim 1, wherein said non-acidic groups are esterified sulphonic acid groups and said acidic groups are sulphonic acid groups.

7. A light-emitting device according to claim 1, wherein said buffer layer comprises PEDOT:PSSA.

8. A light-emitting device according to claim 1, wherein said light-emitting layer comprises a light-emitting polymer.

9. A light-emitting device according to claim 8, which is a polymer light-emitting diode (PLED).

10. A light-emitting device according to claim 1 wherein said light-emitting layer comprises a light-emitting small organic molecule.

11. A light-emitting device according to claim 10, which is an organic light-emitting diode (OLED).

12. A method for manufacturing a light-emitting device comprising:
providing an anode;
providing a cathode;
arranging a light-emitting layer between said anode and said cathode;
arranging a buffer layer, comprising a conducting polymer and a polymeric acid, between said anode and said light-emitting layer; and
performing a conversion of acidic groups of said polymeric acid to non-acidic groups in at least a part of said buffer layer.

13. A method according to claim 12, wherein said conversion of acidic groups of said polymeric acid to non-acidic groups is performed in a part of said buffer layer facing said light-emitting layer.

14. A method according to claim 12, wherein said conversion of acidic groups of said polymeric acid to non-acidic groups is performed on a surface of said buffer layer before arranging said light-emitting layer on said surface.

15. A method according to claim 12, wherein said conversion is performed by esterification with an esterification agent.

16. A method according to claim 15, wherein said esterification is performed by spin coating or ink jet printing of said esterification agent onto said buffer layer, and then esterifying said acidic groups.

17. A method according to claim 16, wherein said esterification agent is an orthoformate having the general formula (I): 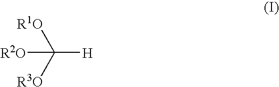
in which R¹, R², and R³, being identical or different, are selected from linear, branched or cyclic alkyl groups having from 1 to 20 carbon atoms, wherein, in said alkyl groups, one or more not neighbouring CH₂-groups are optionally substituted by —O—, —S—, —P—, —Si—, —CO—, —COO—, —O—CO—, —N-alkyl-, —N-aryl- or —CON-alkyl-, and one or more H-atoms are optionally substituted by CN, Cl, F or an aryl group.

18. A method according to claim 17, wherein said esterification agent is triethylorthoformate.

19. A method according to claim 12, wherein said non-acidic groups are esterified sulphonic acid groups, and said acidic groups are sulphonic acid groups.

20. A method according to claim 12, wherein said buffer layer comprises PEDOT:PSSA.

21. A method according to claim 12, wherein said light-emitting layer comprises a light-emitting polymer.

22. A method according to claim 21, wherein said light-emitting device is a polymer light-emitting diode (PLED).

23. A method according to claim 12, wherein said light-emitting layer comprises a light-emitting small organic molecule.

24. A light-emitting device according to claim 23, which is an organic light-emitting diode (OLED).
